(19) United States
(12) Patent Application Publication
(10) Pub. No.: US 2004/0185579 A1
(43) Pub. Date: Sep. 23, 2004

(54) Method of manufacturing semiconductor device

(75) Inventor: Mitsushi Fujiki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Fujitsu Limited, Kawasaki (JP)

(21) Appl. No.: 10/772,253

(22) Filed: Feb. 6, 2004

(30) Foreign Application Priority Data
Mar. 19, 2003 (JP) 2003-075761

(51) Int. Cl. H01L 21/00

(52) U.S. Cl. 438/3; 438/396; 438/389

(57) ABSTRACT

Provided is a method of manufacturing a semiconductor device includes forming an interlayer insulating film above a silicon (semiconductor) substrate, forming an lower layer of a lower-electrode conductive film on the interlayer insulating film while keeping the substrate temperature at a temperature higher than room temperature and lower than 300° C., forming an upper layer of the lower-electrode conductive film on the lower layer and setting the upper and lower layers as the lower-electrode conductive film, forming a ferroelectric film on the lower-electrode conductive film, forming an upper-electrode conductive film on the ferroelectric film, and forming a ferroelectric capacitor by patterning the upper-electrode conductive film, the ferroelectric film, and the lower-electrode conductive film.

### CROSS-REFERENCE TO RELATED APPLICATIONS

This application is based upon and claims priority of Japanese Patent Application No. 2003-075761, filed on Mar. 19, 2003, the contents being incorporated herein by reference.

### BACKGROUND OF THE INVENTION

1. Field of the Invention

The present invention relates to a method of manufacturing a semiconductor device and, more particularly, to a method of manufacturing a semiconductor device having a ferroelectric capacitor.

2. Description of the Related Art

There are several types of nonvolatile memories, in which information remains even when the power is turned off. Among other tings, ferroelectric random access memories (FeRAMs) have drawn an attention in recent years because of its high-speed operation and low-voltage operation.

An FeRAM has a ferroelectric capacitor formed by stacking a lower electrode, a capacitor ferroelectric film, and an upper electrode in this order, and stores information by relating two polarization directions of the capacitor ferroelectric film to “0” and “1,” respectively. The separation between “0” and “1” becomes easy as the magnitude of polarization of the capacitor ferroelectric film increases. In order to achieve this, favorable crystallinity is required for the capacitor ferroelectric film.

Capacitor ferroelectric films generally used include a PZT (Pb(Zrₓ,Ti₁₋ₓ)O₃) film. This PZT film is polarized in the (001) direction. Therefore, in the PZT film, spontaneous polarization is maximized by aligning its orientation to the (001) direction but, in general, the orientation cannot be aligned to the (001) direction. Instead, it is in general performed to gain spontaneous polarization by aligning the orientation to the (111) direction.

The direction of orientation of the PZT film becomes the same as that of the orientation of the lower electrode. Further, the degree of orientation of the PZT film is increased as the orientation of the lower electrode is improved. Therefore, the spontaneous polarization of the PZT film can be improved by forming the lower electrode from a material highly oriented in the same direction as that of PZT (111). In general, a Pt film oriented in the (222) direction, which is the same direction as the (111) direction, is employed as the lower electrode.

However, if the Pt film is formed directly on an insulating film, the Pt film is apt to be peeled off from the insulating film. Accordingly, as in Patent Literature 1, the following has been proposed: the Pt film is formed on an adhesion film, such as a Ti (titanium) film, and the lower electrode is constituted by the Ti film and the Pt film.

In this case, the orientation of the Ti film affects the orientation of the Pt film thereon, and ultimately influences the orientation of the capacitor ferroelectric film. Therefore, a method of depositing a Ti film which is highly oriented in the (002) direction is desired.

For example, Non-patent Literature 1 discloses a method of improving the orientation of a Ti film in the (002) direction by heating a substrate to 350° C. and adding H₂O to a sputtering atmosphere of Ti, and the result thereof.

(Patent Literature 1)

Japanese Unexamined Patent Publication No. Hei 9(1997)-53188

(Non-patent Literature 1)

Jpn. J. Appl. Phys. Vol. 36 (1997) pp. L154-L157 Part 2, No. 2A, February 1997

Out of the above-described prior art, Patent Literature 1 proposes the following method: a Pt film, which is to be an underlying layer of a lead titanate-based ferroelectric thin film, is oriented in the (200) direction, thereby orienting the ferroelectric thin film on the Pt film in the c-axis direction, which is the polarization direction of the ferroelectric thin film, and maximizing the spontaneous polarization of the ferroelectric thin film.

However, according to Patent Literature 1, complicated steps of (i) forming a Pt—Pb alloy thin film, (ii) oxidizing the Pt—Pb alloy thin film, and (iii) removing a PbO layer formed in the oxidation are required for orienting the Pt film in the (200) direction. Therefore, an FeRAM process becomes complicated.

Accordingly, for consistency between the prevention of complication of the process and the increase of spontaneous polarization of the PZT film, it is preferable to highly orient the Pt film in the (222) direction, in which the Pt film is easy to orient, rather than to forcedly orient the Pt film in the (200) direction, in which the Pt film is hard to orient. For achieving this, the orientation of the underlying Ti film also needs to be improved.

### SUMMARY OF THE INVENTION

According to one aspect of the present invention, provided is a method of manufacturing a semiconductor device, comprising: forming an insulating film above a semiconductor substrate; forming a lower layer of a lower-electrode conductive film on the insulating film while keeping substrate temperature at a temperature higher than room temperature and lower than 300° C.; forming an upper layer of the lower-electrode conductive film on the lower layer, and constituting a lower-electrode conductive film by the upper and lower layers; forming a ferroelectric film on the lower-electrode conductive film; forming an upper-electrode conductive film on the ferroelectric film; and forming a ferroelectric capacitor by patterning the upper-electrode conductive film, the ferroelectric film, and the lower-electrode conductive film.

According to the present invention, when the lower layer of the lower-electrode conductive film is deposited, the substrate temperature is kept at a temperature higher than room temperature and lower than 300° C. An experiment has clarified that the above induces the strong orientation of the lower layer in a specified direction and that the degree of orientation of the upper layer is also improved along with the foregoing. As a result, the orientation of the ferroelectric layer formed on the upper layer is also improved. Therefore, the stable mass production of ferroelectric capacitors having large magnitudes of spontaneous polarization can be realized.

### BRIEF DESCRIPTION OF THE DRAWINGS

FIGS. 1A to 1P are cross-sectional views showing a process of forming a semiconductor device according to an embodiment of the present invention;

FIG. 2 is a graph obtained by investigating the relationship between the deposition temperature of a Ti film and the degree of orientation of the Ti film in the (002) direction by XRD;

FIG. 3 is a graph obtained by investigating the relationship between the deposition temperature of the Ti film and the degree of orientation in the (222) direction of a Pt film formed on the Ti film by XRD; and

FIG. 4 is a graph obtained by investigating the degree of orientation of a PZT film on the Pt film in the (111) direction by XRD in the case where the degree of orientation of the Pt film on the Ti film in the (222) direction is changed by changing the deposition temperature of the Ti film.

### DETAILED DESCRIPTION OF THE PREFERRED EMBODIMENT

Hereinafter, an embodiment of the present invention will be described based on the accompanying drawings.

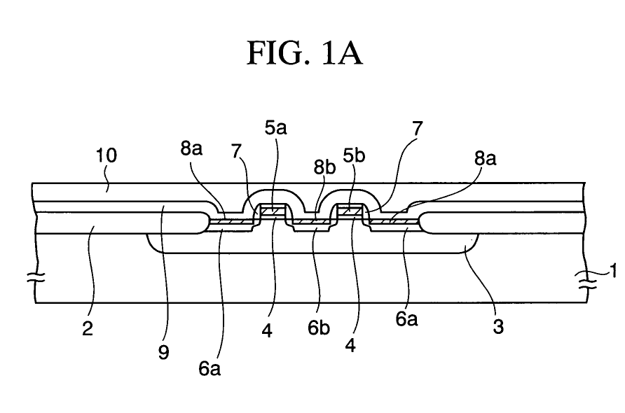

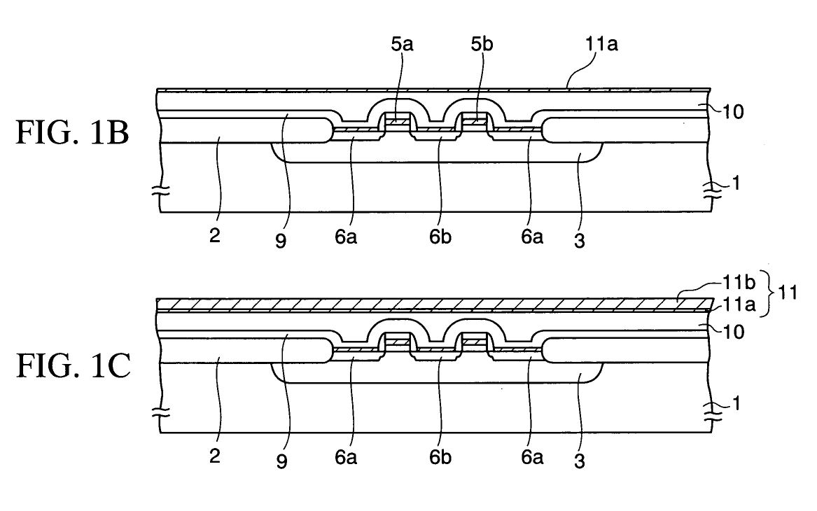

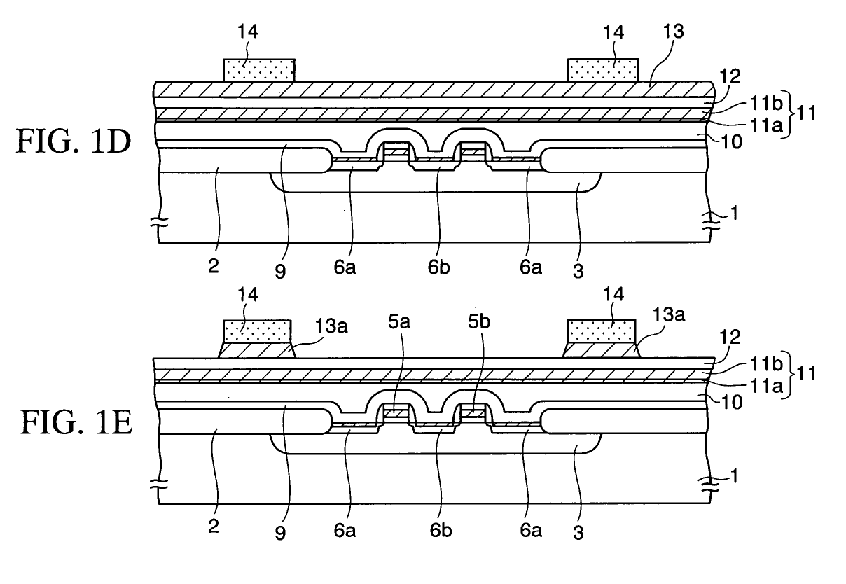

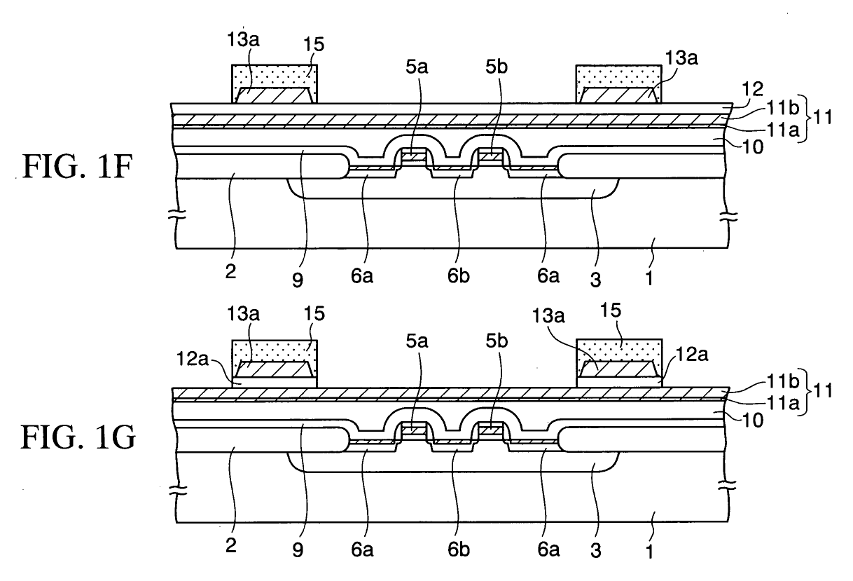

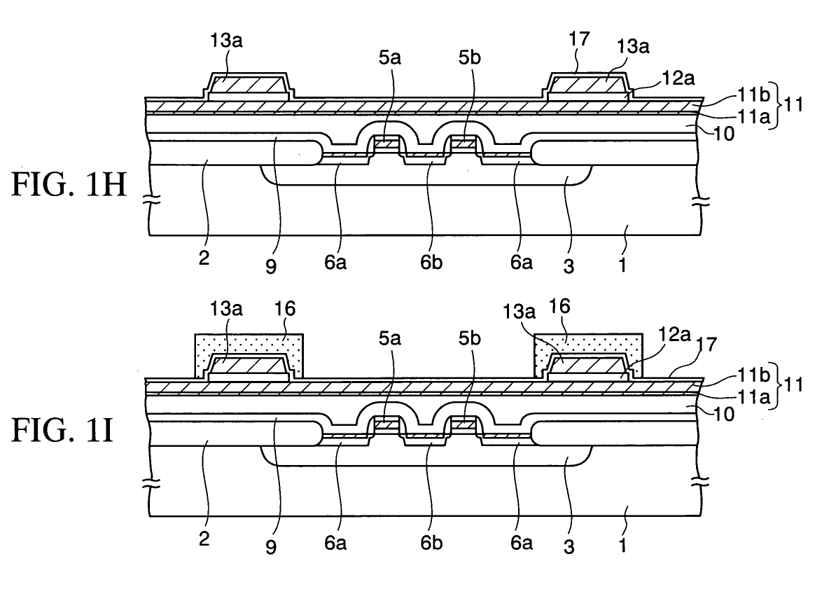

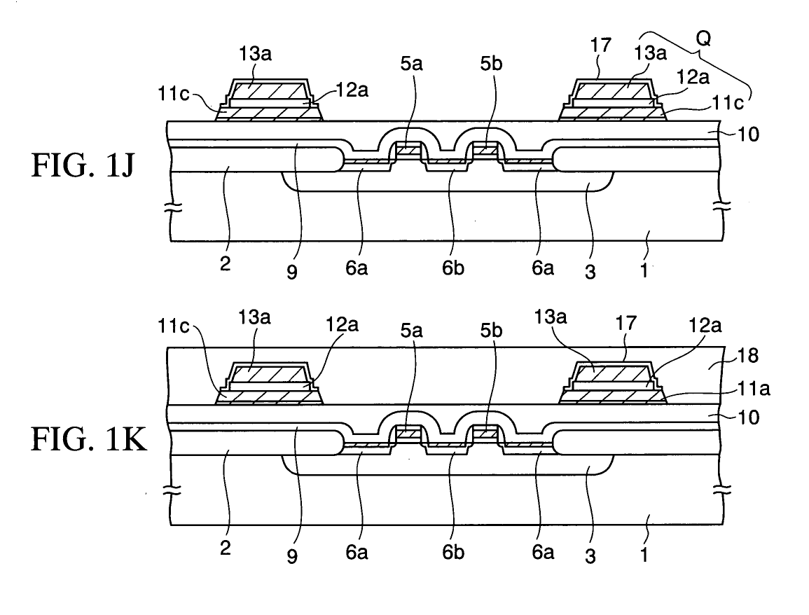

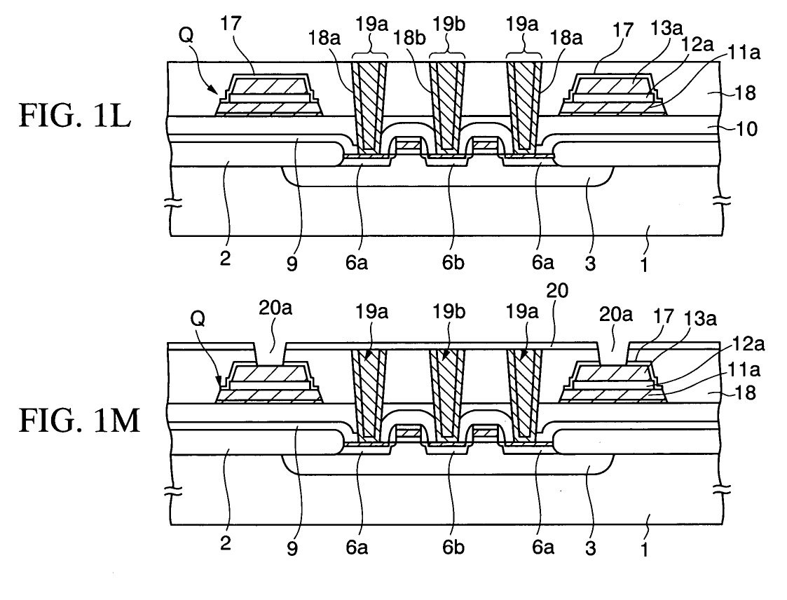

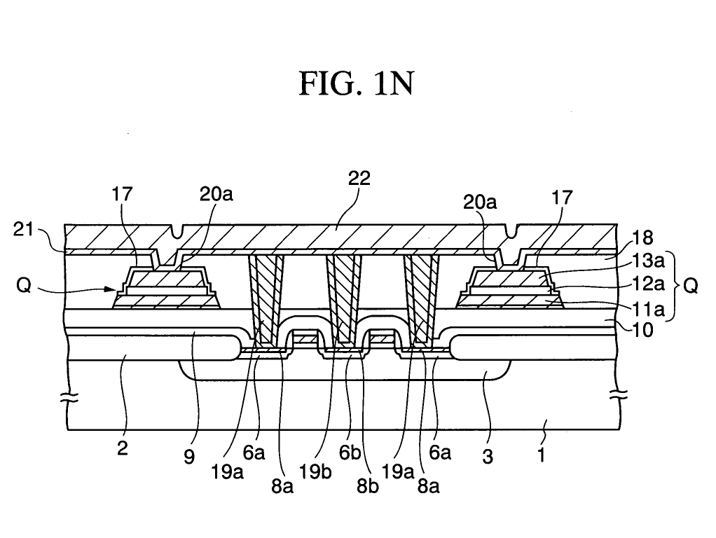

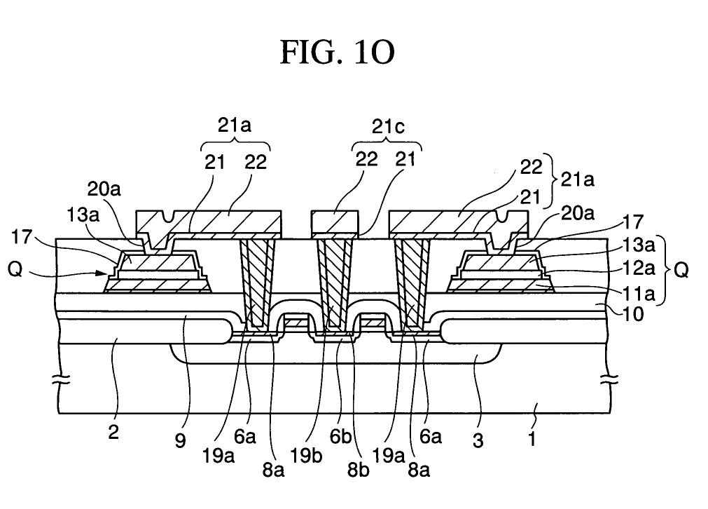

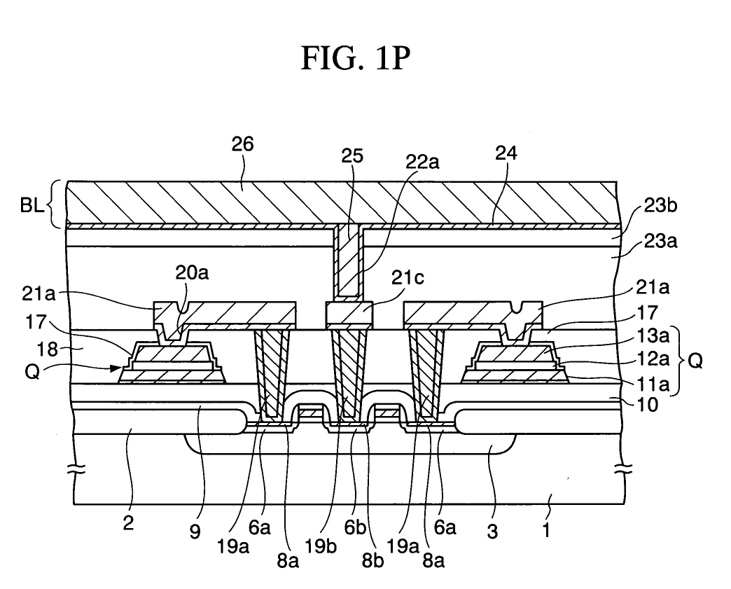

FIGS. 1A to 1P are cross-sectional views showing a process of forming a semiconductor device according to the embodiment of the present invention.

First, steps until the cross-sectional structure shown in FIG. 1A is formed will be described.

An element isolation insulating film 2 is formed on the surface of an n-type or p-type silicon (semiconductor) substrate 1 by LOCOS (local Oxidation of Silicon) method. STI (Shallow Trench Isolation) may be adopted for the element isolation insulating film 2.

After such an element isolation insulating film 2 is formed, a p-well 3 is formed in a predetermined active region (transistor formation region) in a memory cell region of the silicon substrate 1.

Thereafter, the surface of the active region of the silicon substrate 1 is thermally oxidized to form a silicon oxide film, and the silicon oxide film is used as gate insulating films 4.

Next, a conductive film made of polysilicon or refractory metal silicide is formed on the entire upper surface of the silicon substrate 1. After that, the conductive film is patterned into a predetermined shape by photolithography, thus forming gate electrodes 5a and 5b on the gate insulating films 4. The two gate electrodes 5a and 5b are arranged almost parallel to each other on one p-well 3 in the memory cell region. These gate electrodes 5a and 5b constitute a part of word lines.

Subsequently, an n-type impurity is ion-implanted into the p-well 3 on both sides of the gate electrodes 5a and 5b, thus forming n-type impurity diffusion regions 6a and 6b, which are to be source/drain electrodes of n-channel MOS transistors. Further, after an insulating film is formed on the entire surface of the silicon substrate 1, the insulating film is left as sidewall insulating films 7 on both sides of the gate electrodes 5a and 5b by etch back of the insulating film. The insulating film is, for example, a silicon oxide (SiO₂) film formed by CVD.

Furthermore, n-type impurity ions are again ion-implanted into the well 3 using the gate electrodes 5a and 5b and the sidewall insulating films 7 as a mask, whereby the n-type impurity diffusion regions 6a and 6b are formed into LDD (Lightly Doped Drain) structures. Incidentally, in one p-well 3, the n-type impurity diffusion region 6b interposed between the two gate electrodes 5a and 5b is to be electrically connected to a bit line, which is described later. On the other hand, the two impurity diffusion regions 6a closer to both side edges of the p-well 3 are to be electrically connected to capacitor upper electrodes, which are described later.

As described above, in the p-well 3 of the memory cell region, the two n-type MOSFETs are constituted by the gate electrodes 5a and 5b, the n-type impurity diffusion regions 6a and 6b, and the like.

Next, after a refractory metal film has been formed on the entire surface, the refractory metal film is heated to form refractory metal silicide layers 8a and 8b on the surfaces of the n-type impurity diffusion regions 6a and 6b, respectively. Thereafter, the unreacted refractory metal film is removed by wet etching.

Furthermore, a silicon oxynitride (SiON) film is formed to a thickness of approximately 200 nm as a cover film 9 for covering MOS transistors on the entire surface of the silicon substrate 1 by plasma CVD. Further, silicon dioxide (SiO₂) is grown as a first interlayer insulating film 10 to a thickness of approximately 1.0 μm on the cover film 9 by plasma CVD in which TEOS gas is used. Then, the first interlayer insulating film 10 is polished by chemical mechanical polishing (CMP), thus planarizing the upper surface thereof.

Next, steps until the structure shown in FIG. 1B is formed will be described.

First, the silicon substrate 1 is mounted on a heater stage in a Ti sputtering chamber (not shown), the substrate temperature is heated to a temperature higher than room temperature (20° C.), e.g., 150° C., and stabilized. The upper limit of the substrate temperature is not particularly limited but preferably a temperature lower than 300° C.

Furthermore, Ar is supplied as sputtering gas to the inside of the chamber at a flow rate of 50 sccm while the chamber is being evacuated with a vacuum pump (not shown), and the pressure in the chamber is kept at, for example, 3.4×10⁻¹ Pa.

Then, after the atmosphere in the chamber becomes stable, DC power of 2.0 kW is applied to a Ti target, thus starting the sputtering of Ti by DC magnetron sputtering. By keeping this state for, for example, 15 seconds, a Ti film is formed to a thickness of 5 to 50 nm, e.g., approximately 20 nm, on the first interlayer insulating film 10, and the Ti film is used as a lower layer 11a of a lower-electrode conductive film.

The lower layer 11a has the function of improving the adhesiveness between the first interlayer insulating film 10 and undermentioned lower electrodes to prevent the lower electrodes from being peeled off from the first interlayer insulating film 10.

Incidentally, instead of a Ti film, an alloy film made of an alloy of Ti and noble metal may be formed as the lower layer 11a. Such alloy films include, for example, a Pt—Ti alloy film, an Ir—Ti alloy film, a Ru—Ti alloy film, and the like.

Thereafter, as shown in FIG. 1C, a Pt film having a thickness of approximately 175 nm is formed as an upper layer 11b of the lower-electrode conductive film by DC magnetron sputtering. Deposition conditions for the Pt film are, for example, as follows: the substrate temperature is 100° C., the DC power is 1.0 kW, the Ar flow rate is 100 sccm, and the pressure is 5.0×10⁻¹ Pa.

According to this, the lower-electrode conductive film 11 constituted by the lower and upper layers 11a and 11b has been formed on the first interlayer insulating film 10.

It should be noted that, instead of a single-layer Pt film, a single-layer film or a multilayer film made of any one of iridium (Ir), ruthenium (Ru), palladium (Pd), platinum oxide (PtOₓ), iridium oxide (IrOₓ), ruthenium oxide (RuOₓ), palladium oxide (PdOₓ), and an alloy of any one of the foregoing may be formed.

Next, steps until the cross-sectional structure shown in FIG. 1D is obtained will be described.

First, the silicon substrate 1 is mounted on a heater stage provided in a sputtering chamber (not shown) for Pb(Zr,Ti)O₃ (PZT), and the silicon substrate 1 is heated to approximately 50° C. Then, Ar for sputtering is supplied to the inside of the chamber at a flow rate of 15 to 25 sccm, and the chamber is evacuated with a vacuum pump. When the pressure in the chamber becomes stable, RF power having a frequency of 13.56 MHz and a power of 1.0 kW is applied to a PZT target, whereby a PZT film is formed to a thickness of approximately 175 nm on the lower-electrode conductive film 11 by RF sputtering and the PZT film is used as a ferroelectric film 12.

The amount of Pb in this ferroelectric film 12 can be controlled by adjusting the flow rate of Ar used for sputtering. Moreover, a method of depositing the ferroelectric film 12 is not limited to sputtering but may be the spin-on method, the sol-gel method, metal organic deposition (MOD), or metal organic CVD (MOCVD). Furthermore, in accordance with desired characteristics of capacitors, PZT constituting the ferroelectric film 12 may be doped with a small amount of calcium (Ca), strontium (Sr), lanthanum (La), or the like.

Examples of material constituting the ferroelectric film 12 include, other than PZT, SrTiO₃, (Ba,Sr)TiO₃, (Pb,La)(Ar,Ti)O₃, Bi layered compounds, such as SrBi₂(TaₓNb₁₋ₓ)₂O₉ (0<x≦1) and Bi₄Ti₂O₁₂, and the like.

Thereafter, PZT constituting the ferroelectric film 12 is crystallized by annealing the ferroelectric film 12 in an oxygen-containing atmosphere. As this annealing, two-step rapid thermal annealing (RTA) is adopted. In the first step, conditions are an Ar atmosphere with an oxygen concentration of 2.5%, a substrate temperature of 600° C., and a processing time of 90 seconds; in the second step, conditions are an oxygen concentration of 100%, a substrate temperature of 750° C., and a processing time of 60 seconds.

Subsequently, an IrOx layer is formed to a thickness of approximately 200 nm as an upper-electrode conductive film 13 on the ferroelectric film 12 by two-step DC magnetron sputtering. As conditions for the first step, a DC power of 1.04 kW, an Ar flow rate of 100 sccm, an O₂ flow rate of 100 sccm, a substrate temperature of 20° C., and a deposition time of 29 seconds are employed; as conditions for the second step, a DC power of 2.05 kW, an Ar flow rate of 100 sccm, an O₂ flow rate of 100 sccm, a substrate temperature of 20° C., and a deposition time of 22 seconds are employed.

It should be noted that a platinum film or a strontium ruthenium oxide (SRO) film may be formed as the upper-electrode conductive film 13 by sputtering.

Thereafter, resist is coated onto the upper-electrode conductive film 13, and this resist is exposed and developed, whereby a first resist pattern 14 having the shapes of upper electrodes is formed.

Next, as shown in FIG. 1E, the upper-electrode conductive film 13 is etched using the first resist patter 14 as a mask, and the upper-electrode conductive films 13 thus left are used as capacitor upper electrodes 13a.

After the first resist pattern 14 has been removed, the ferroelectric film 12 is annealed through the capacitor upper electrodes 13a in an oxygen atmosphere under the following conditions: a temperature of 650° C. and 60 minutes. This annealing is performed for recovering the ferroelectric film 12 from the damage caused to the ferroelectrics film during sputtering and etching.

Next, resist is coated onto the capacitor upper electrodes 13a and the ferroelectric film 12, and this resist is exposed and developed, whereby a second resist pattern 15 as shown in FIG. 1F is formed.

After that, as shown in FIG. 1G, the ferroelectric film 12 is etched using the second resist pattern 15 as a mask, and the ferroelectric films 12 thus patterned are used as capacitor dielectric films 12a.

After the second resist pattern 15 has been removed, the capacitor dielectric films 12a are annealed in an oxygen atmosphere at a temperature of 650° C. for 60 minutes.

Furthermore, as shown in FIG. 1H, an Al₂O₃ film is formed to a thickness of 50 nm as an encapsulating layer 17 on the capacitor upper electrodes 13a, the capacitor dielectric films 12a, and the lower-electrode conductive film 11 by sputtering at room temperature. This encapsulating layer 17 is formed in order to protect the capacitor dielectric films 12a, which are apt to be reduced, from hydrogen. A PZT film, a PLZT film, or a titanium oxide film may be formed as the encapsulating layer 17.

Thereafter, the quality of the capacitor dielectric films 12a is improved by rapid thermal annealing of the capacitor dielectric films 12a under the encapsulating layer 17 in an oxygen atmosphere under the following conditions: 700° C., 60 seconds, and a heat up rate of 125° C./sec.

Next, as shown in FIG. 1I, resist is coated onto the encapsulating layer 17, and this resist is exposed and developed, whereby a third resist pattern 16 having the shapes of capacitor lower electrodes is formed on the capacitor dielectric films 12a.

After that, as shown in FIG. 1J, the encapsulating layer 17 and the upper-electrode conductive film 11 are etched using the third resist pattern 16 as a mask, and the upper-electrode conductive films 11 thus left under the third resist pattern 16 are used as capacitor lower electrodes 11c. Then, the third resist pattern 16 is removed.

According to this, ferroelectric capacitors Q each having the capacitor lower electrode 11c, the capacitor dielectric film 12a, and the capacitor upper electrode 13a stacked in this order therein is formed on the first interlayer insulating film 10.

Subsequently, the capacitor dielectric films 12a are recovered from damage by annealing the capacitor dielectric films 12a in an oxygen atmosphere under the following conditions: a temperature of 650° C. and 60 minutes.

Next, as shown in FIG. 1K, an SiO₂ film having a thickness of 1200 nm is formed as a second interlayer insulating film 18 on the ferroelectric capacitors Q and the first interlayer insulating film 10 by CVD, and then the surface of the second interlayer insulating film 18 is planarized by CMP. The growth of the second interlayer insulating film 18 may be performed using silane (SiH₄) or TEOS as reactive gas. The planarization of surface of the second interlayer insulating film 18 is performed until the thickness thereof becomes 200 nm from the upper surfaces of the capacitor upper electrodes 13a.

Next, steps until the structure shown in FIG. 1L is formed will be described.

First, the first and second interlayer insulating films 10 and 18 and the cover film 9 are patterned, thus forming contact holes 18a and 18b on the n-type impurity diffusion layers 6a and 6b. As an etching gas for the first and second interlayer insulating films 10 and 18 and the cover film 9, a CF-based gas, e.g., a mixed gas in which Ar is added to CF₄, is used.

Then, a titanium (Ti) film having a thickness of 20 nm and a titanium nitride (TiN) film having a thickness of 50 nm are formed on the upper surface of the second interlayer insulating film 18 and the inner surfaces of the contact holes 18a and 18b by sputtering, and the titanium film and the titanium nitride film are used as an adhesion layer. Furthermore, a tungsten film is formed on the adhesion layer by CVD in which gas mixture of tungsten fluoride (WF₆), argon, and hydrogen is used, thus completely filling the contact holes 18a and 18b.

In addition, the tungsten film and the adhesion layer on the second interlayer insulating film 15 are removed by CMP, and the tungsten film and the adhesion layer are left only in contact holes 18a and 18b. Thus, the tungsten film and the adhesion layer in the contact holes 18a and 18b are used as conductive plugs 19a and 19b.

Incidentally, in one p-well 3 in the memory cell region, the first conductive plug 19b on the center n-type impurity diffusion region 6b interposed between the two gate electrodes 5a and 5b is electrically connected to a bit line, which is described later. On the other hand, the two second conductive plugs 19a on both sides of the first conductive plug 19b are electrically connected to the capacitor upper electrodes 13a through interconnections, which are described later.

Thereafter, the second interlayer insulating film 18 is heated in a vacuum chamber at a temperature of 390° C., whereby water is expelled to the outside.

Next, steps until the structure shown in FIG. 1M is formed will be described.

First, a SiON film is formed to a thickness of, for example, 100 nm as an anti-oxidation film 20 on the second interlayer insulating film 18 and the conductive plugs 19a and 19b by plasma CVD. This SiON film is formed using a mixed gas of silane (SiH₄) and N₂O.

Subsequently, a photoresist (not shown) is coated onto the anti-oxidation film 20, and this photoresist is exposed and developed, thus forming windows on the capacitor upper electrodes 13a. Thereafater, the encapsulating layers 17, the second interlayer insulating film 18, and the anti-oxidation film 20 are etched using the photoresist as a mask, thereby forming contact holes 20a on the capacitor upper electrodes 13a.

Then, after the photoresist (not shown) has been removed, the quality of the capacitor dielectric films 12a is improved by annealing the capacitor dielectric films 12a in an oxygen atmosphere under the following conditions: 550° C. and 60 minutes. In this case, the conductive plugs 19a and 19b are prevented from being oxidized, by the anti-oxidation film 20.

Next, steps until the structure shown in FIG. 1N is formed will be described.

First, the anti-oxidation film 20 is removed by dry etching using a CF-based gas.

After that, a titanium nitride (TiN) film is formed as an underlying conductive film 21 on the second interlayer insulating film 18, the conductive plugs 19a and 19b, and the inner surfaces of the contact holes 20a by sputtering. The underlying conductive film 21 functions as a barrier film having good adhesiveness to an aluminum film, which is described later. The material for the underlying conductive film 21 is not limited to titanium nitride but may be a stacked structure of titanium nitride and titanium, or may be tungsten nitride.

Then, an aluminum film 22 is formed on the underlying conductive film 21 by sputtering. The aluminum film 22 is formed so as to have a thickness of approximately 500 nm on the second interlayer insulating film 18. In some cases the aluminum film 22 may contain copper.

Subsequently, as shown in FIG. 1O, the aluminum film 22 and the underlying conductive film 21 are patterned by photolithography, thus forming a via contact pad 21c on the conductive plug 19b at the center of the p-well 3, and forming upper-electrode-extracting interconnections 21a connecting the conductive plugs 19a which are placed at both sides of the via contact pad 21c to the upper surfaces of the capacitor upper electrodes 13a through the contact holes 20a.

Thus, the capacitor upper electrodes 13a are electrically connected to the n-type impurity diffusion regions 6a closer to the both edges of the p-well 3 through the upper-electrode-extracting interconnections 21a, the conductive plugs 19a, and the refractory metal silicide layers 8a, respectively.

It should be noted that long-through sputtering may be used as the sputtering for the formation of the underlying conductive film 21 and the aluminum film 22.

Next, steps until the structure of FIG. 1P is formed will be described.

First, a SiO₂ film is formed to a thickness of 2300 nm as a third interlayer insulating film 23a by plasma CVD in which TEOS is used as a source. Thus, the second interlayer insulating film 18, the upper-electrode-extracting interconnections 21a, and the contact pad 21c are covered with the third interlayer insulating film 23a. Subsequently, the surface of the third interlayer insulating film 23a is planarized by CMP.

Furthermore, a protective insulating film 23b made of SiO₂ is formed on the third interlayer insulating film 23a by plasma CVD using TEOS. Then, the third interlayer insulating film 23a and the protective insulating film 23b are patterned, thus forming a hole 22a on the contact pad 21c existing above the center of the p-well 3 in the memory cell region.

Next, an adhesion layer 24 made of titanium nitride (TiN) having a film thickness of 90 to 150 nm is formed on the upper surface of the protective insulating film 23b and the inner surface of the hole 22a by sputtering. After that, the substrate temperature is set to approximately 400° C., and a blanket tungsten film 25 is formed so as to fill the hole 22a, by CVD in which WF₆ is used.

Next, the blanket tungsten film 25 is left only in the hole 22a by etch back, and the blanket tungsten film 25 in the hole 22a is used as a second-layer conductive plug.

Thereafter, a metal film 26 is formed on the adhesion layer 24 and the blanket tungsten film 25 by sputtering. Subsequently, the metal film 26 is patterned by photolithography, thus forming a bit line BL electrically connected to the n-type impurity diffusion region 6b through the second-layer conductive plug 25, the contact pad 21c, the first-layer conductive plug 19b, and the refractory metal silicide layer 8b.

In the above-described embodiment, when a Ti film has been formed as the lower layer 11a of a lower-electrode conductive film by sputtering, the substrate temperature is kept at a temperature higher than room temperature. The inventor of the present application speculated that the orientation of the Ti film might depend on the substrate temperature of Ti deposition, and conducted an experiment described below.

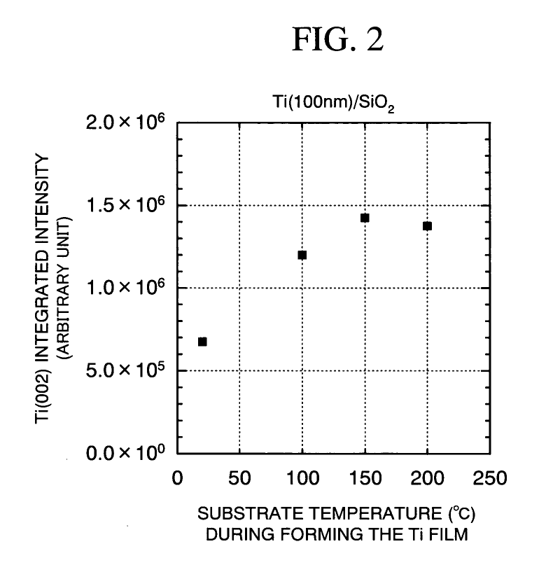

In this experiment, a Ti film was formed to a thickness of 100 nm on a SiO₂ film by the already described DC magnetron sputtering while the substrate temperature during the formation of the Ti film was being variously changed, and the degree of orientation of the Ti film in the (002) direction was measured by X-ray diffraction (XRD) for samples of the respective substrate temperatures. The results are shown in FIG. 2.

The horizontal axis of FIG. 2 represents the substrate temperature, and the vertical axis thereof represents the integrated intensity of X-rays in the (002) direction of Ti.

As shown in FIG. 2, it is understood that the orientation of the Ti film is smallest in the case where the substrate temperature is room temperature (20° C.) and that the degree of orientation also increases as the substrate temperature increases beyond room temperature. However, the degree of orientation turns into a downward trend after becoming maximum at around 150° C. It can be seen by extending the graph that the degree of orientation at around 300° C. becomes almost the same as that at room temperature. These show that the degree of orientation of a Ti film in the (002) direction can be improved by setting the substrate temperature during the deposition of the Ti film higher than room temperature and lower than 300° C.

Although the orientation direction of the Ti film becomes the (002) direction as described previously, this does not mean that the entire Ti film is oriented in the (002) direction, but means that the Ti film has the peak of a diffraction line in the (002) direction when observed by XRD, and that the orientation in the (002) direction becomes dominant in the Ti film. This holds also for a Pt film and a PZT film, which are described later.

In particular, by setting the substrate temperature to 50° C. to 250° C., the integrated intensity of the Ti film in the (002) direction becomes a significantly high value of approximately 1.0×10¹⁶ or more compared to the case where the substrate temperature is set to room temperature.

Moreover, it can be understood by extending the graph that a Ti film strongly oriented in the (002) direction like the above cannot be deposited in the case where the substrate temperature is 350° C.

Such behavior of the degree of orientation of the Ti film is expected to reflect on the orientation of the Pt film formed thereon as the upper layer 11b. In order to confirm this point, the inventor of the present application investigated the relationship between the substrate temperature during the deposition of the Ti film and the degree of orientation of the Pt film thereon. In this experiment, a Ti film was formed to a thickness of 20 nm, and a Pt film was formed to a thickness of 175 nm on the Ti film. The thicknesses and deposition conditions of these films are the same as those of the already described embodiment. Further, the degree of orientation was investigated by XRD similarly to the above.

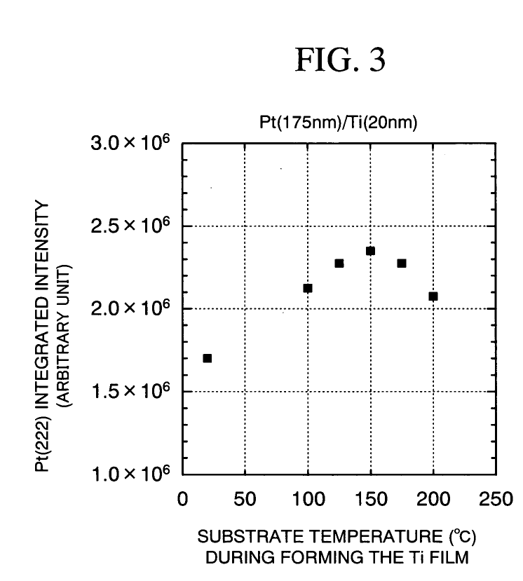

The results of the experiment are shown in FIG. 3. The horizontal axis of FIG. 3 represents the substrate temperature during the deposition of the Ti film, and the vertical axis thereof represents the integrated intensity of X-rays in the (222) direction of Pt.

As shown in FIG. 3, the degree of orientation of the Pt film in the (222) direction also exhibits almost the same tendency as that of the aforementioned FIG. 2. It is understood that the orientation of the Pt film can be improved by setting the substrate temperature higher than room temperature and lower than 300° C.

Furthermore, the inventor of the present application formed a PZT film on the lower electrode constituting of the Ti film and the Pt film, and changed the degree of orientation of the Pt film on the Ti film in the (222) direction by changing the substrate temperature during the deposition of the Ti film as described previously, thereby conducting an experiment on how the degree of orientation of the PZT film in the (111) direction changed. In this experiment, the Pt film was formed to a thickness of 175 nm, and the PZT film was formed to a thickness of approximately 200 nm. Moreover, the degree of orientation of the PZT film was investigated by XRD.

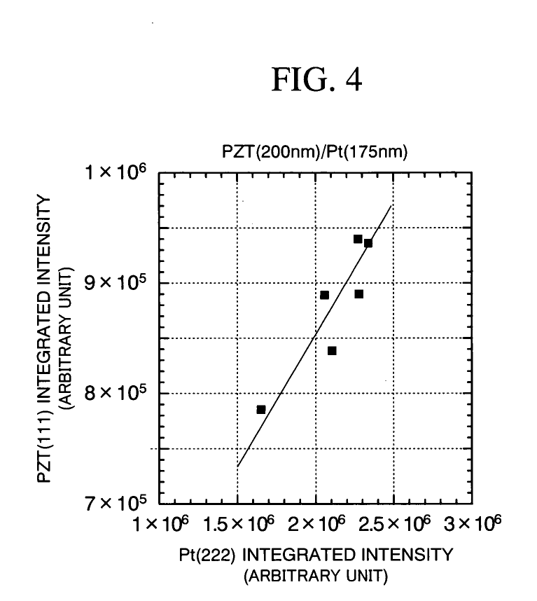

The results are shown in FIG. 4. As the degree of orientation of the Pt film in the (222) direction increases, the degree of orientation of the PZT film in the (111) direction increases. Therefore, it is understood that the degree of orientation of the PZT film can be improved by setting the substrate temperature during the deposition of the Ti film as already described and thereby improving the orientation of the Pt film on the Ti film.

As described above, by setting the substrate temperature higher than room temperature and lower than 300° C. when the Ti film is formed as the lower layer 11a of the lower-electrode conductive film 11 by sputtering, the degree of orientation of the Ti film is improved and, as a result, the degree of orientation of the ferroelectric film 12 is also improved. Accordingly, the stable mass production of ferroelectric capacitors Q having large magnitudes of spontaneous polarization can be realized.

In addition, according to the above, the degree of orientation of the ferroelectric film is improved by a simple method in which the substrate temperature during the deposition of the Ti film is controlled. Accordingly, it is possible to immediately apply this method to a current mass production process without changing the existing process. Therefore, a process cost does not substantially increase, and the complication of a process as in Patent Literature 1 cannot be caused.

On the other hand, in Non-patent Literature 1, a Ti film is formed while the substrate temperature is being set to 350° C. However, the results of the experiment shown in FIG. 2 show that the orientation at the same level as that of a Ti film deposited at room temperature is barely obtained in this method.

Moreover, if the substrate temperature is set to the aforementioned range and H₂O is added to the sputtering atmosphere for Ti, the orientation of a Ti film is expected to be further improved because the strengthening of the orientation due to H₂O is added in addition to the strengthening of the orientation of the Ti film due to the substrate temperature.

Furthermore, the result of another experiment has been confirmed that the degree of orientation of the Ti film constituting the lower layer 11a in the (002) direction is increased by exposing the surface of the first interlayer insulating film 10 to NH₃ plasma to improve the quality thereof before the lower layer 11a is formed.

As the conditions for the NH₃ plasma processing, for example, the flow rate of NH₃ gas introduced into a chamber (not shown) is set to 350 scam, the pressure in the chamber is set to 1 Torr, the substrate temperature is set to 400° C., the power of a high-frequency source at 13.56 MHz applied to a substrate is set to 100 W, the power of a high-frequency source at 350 kHz supplied to a plasma generation region is set to 55 W, the distance between an electrode and a first interlayer insulating film 10 is set to 50 mils, and the plasma irradiation time is set to 60 seconds.

As described above, according to the present invention, the substrate temperature is kept at a temperature higher than room temperature and lower than 300° C. during the deposition of the lower layer of the lower-electrode conductive film. Therefore, the degree of orientation of the lower layer increases and, under the influence of this, the orientation of the upper layer of the lower-electrode conductive film and that of the ferroelectric film thereon also increase. Accordingly, a ferroelectric capacitor having a large magnitude of spontaneous polarization can be provided.

What is claimed is:

1. A method of manufacturing a semiconductor device, comprising:
forming an insulating film over a semiconductor substrate;
forming a lower layer of a lower-electrode conductive film on the insulating film while keeping substrate temperature at a temperature higher than room temperature and lower than 300° C.;
forming an upper layer of the lower-electrode conductive film on the lower layer, and constituting a lower-electrode conductive film by the upper and lower layers;
forming a ferroelectric film on the lower-electrode conductive film;
forming an upper-electrode conductive film on the ferroelectric film; and
forming a ferroelectric capacitor by patterning the upper-electrode conductive film, the ferroelectric film, and the lower-electrode conductive film.

2. The method according to claim 1, wherein the lower layer of the lower-electrode conductive film is formed by sputtering.

3. The method according to claim 1, wherein any one of a titanium layer and a layer of an alloy of titanium and noble metal is formed as the lower layer of the lower-electrode conductive film.

4. The method according to claim 3, wherein an orientation direction of the lower layer of the lower-electrode conductive film is a (002) direction.

5. The method according to claim 1, wherein any one of a single-layer film and a multilayer film, which are made of any one of platinum, iridium, ruthenium, palladium, platinum oxide, iridium oxide, ruthenium oxide, palladium oxide, and an alloy thereof, is formed as the upper layer of the lower-electrode conductive film.

6. The method according to claim 5, wherein an orientation direction of the upper layer of the lower-electrode conductive film is a (222) direction.

7. The method according to claim 1, wherein any one of a film made of any one of Pb(Zr,Ti)O₃, (Pb,La)(Zr,Ti)O₃, SrTiO₃, (Ba,Sr)TiO₃, SrBi₂(TaₓNb₁₋ₓ)₂O₉(0<x≦1) , and (Pb,La)(Zr,Ti)O₃, and a film made of a material in which Pb(Zr,Ti)O₃ is doped with at least any one of calcium, strontium, and lanthanum is formed as the ferroelectric film.

8. The method according to claim 7, wherein an orientation direction of the ferroelectric film is a (111) direction.

9. The method according to claim 1, wherein quality of the insulating film is improved by exposing a surface of the insulating film to NH₃ plasma before the lower layer of the lower-electrode conductive film is formed.

10. The method according to claim 1, wherein H₂O is added to an atmosphere in which the lower layer of the lower-electrode conductive film is formed.
